(19) United States
(12) Patent Application Publication
(10) Pub. No.: US 2005/0227608 A1
(43) Pub. Date: Oct. 13, 2005

(54) Fan mounting structure

(75) Inventors: Chia-Kang Wu, Taipei City (TW); Yu-Jen Liang, Taipei City (TW); Fu-Jung Hsui, Taipei City (TW)

Correspondence Address: BACON & THOMAS, PLLC, 625 SLATERS LANE, FOURTH FLOOR, ALEXANDRIA, VA, 22314, US

(73) Assignee: Tatung Co., Ltd., Taipei City (TW)

(21) Appl. No.: 10/923,778

(22) Filed: Aug. 24, 2004

(30) Foreign Application Priority Data
Apr. 6, 2004 (TW) 093205212

(51) Int. Cl. H05K 5/00

(52) U.S. Cl. 454/184

(57) ABSTRACT

A fan mounting structure is disclosed to include a mounting frame directly affixed to the border area of the air outlet of a fan with screws for securing the fan to a fan rack, having a side plate covering over one lateral side of the peripheral wall of the fan. The open type design of the mounting frame fits any of a variety of fans that have different height and shapes.

### BACKGROUND OF THE INVENTION

1. Field of the Invention

The present invention relates to a fan mounting structure and more particularly, to a mounting frame that fits any of a variety of fans having different depths and different shapes.

2. Description of Related Art

A computer has many electronic devices that generate heat during system running. If the heat is not quickly dissipated out of the computer, the computer may been shutdown. According to conventional methods, a cooling fan is mounted in the computer or directly mounted on the heat emitting electronic device to expel heat out of the computer.

When using a fan in a computer, the fan is fastened to a mounting frame, and then the mounting frame is mounted in a fan bracket inside the computer or directly secured to the heat emitting electronic device. FIG. 1 illustrates a mounting frame used with a fan according to the prior art. According to this design, the fan 92 is mounted inside the mounting frame 91. The mounting frame 91 is U-shaped and has three sidewalls 911 surrounding a receiving chamber 912 that accommodates the fan 92.

However, general fans have different height (thickness). The depth of the receiving chamber 912 of the mounting frame 91 must fit the height (thickness) of the fan 92 so that the fan 92 can well received inside the mounting frame 91. Therefore, this structure of mounting frame 91 cannot fit different fans having different height and shapes.

### SUMMARY OF THE INVENTION

The present invention has been accomplished under the circumstances in view. It is therefore the main object of the present invention to provide a mounting frame for fan mounting structure, which fits any of a variety of fans that have different height (thickness).

To achieve this and other objects of the present invention, the fan mounting structure is comprised of a fan and a mounting frame. The fan comprises an air inlet, an air outlet opposite to the air inlet, a peripheral wall peripherally connected between the air inlet and the air outlet, and a plurality of mounting devices provided around one of the air inlet and the air outlet. The mounting frame comprises a plurality of mounting devices respectively fastened to the mounting devices at one of the air inlet and the air outlet fan, and a side plate perpendicularly extended from one lateral side thereof and covering over one lateral side of the peripheral wall of the fan.

As indicated above, the mounting frame is directly fastened to the border area of one of the air outlet and air inlet of the fan, and has only one side plate extended from one lateral side for covering over one side of the peripheral wall of the fan. Therefore, the mounting frame fits any of a variety of fans that have different height.

Further, the side plate of the mounting frame comprises at least one through hole for the passing of the power cable of the fan. The mounting devices of the fan can be screw holes, and the mounting devices of the mounting frame can be mounting through holes respectively fastened to the corresponding screw holes of the fan with respective screws.

### BRIEF DESCRIPTION OF THE DRAWINGS

FIG. 1 is a perspective assembly view of a fan mounting structure according to the prior art.

FIG. 2 is an exploded view of the fan mounting structure according to the present invention.

FIG. 3 is an isometric view of the mounting frame for the fan mounting structure according to the present invention.

FIG. 4 is an assembly view of the present invention.

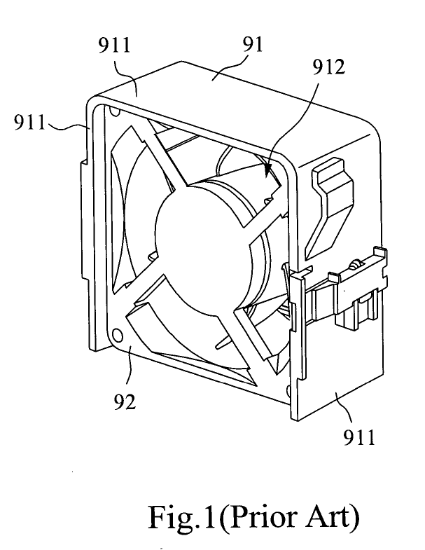

### DETAILED DESCRIPTION OF THE PREFERRED EMBODIMENT

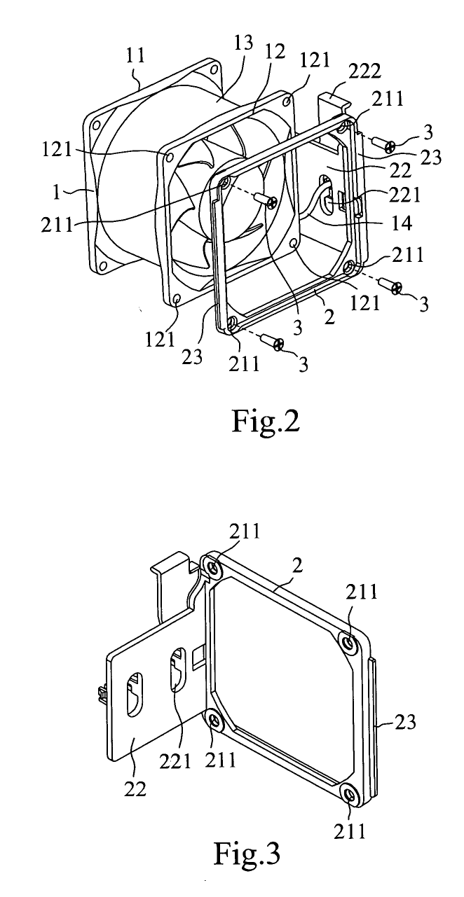

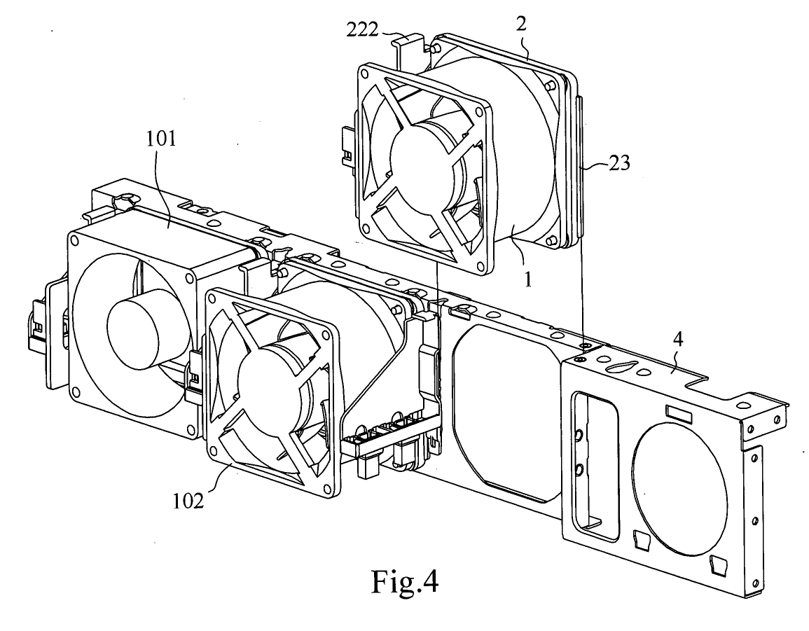

Referring to FIG. 2 and FIG. 3, a fan mounting structure in accordance with the present invention is shown comprised of a fan 1 and a mounting frame 2. The fan 1 and the mounting frame 2 are fastened together.

The fan 1 comprises an air inlet 11, an air outlet 12 opposite to the air inlet 11, a peripheral wall 13 peripherally connected between the air inlet 11 and the air outlet 12, a plurality of mounting devices, for example, screw holes 121 respectively disposed in the four corners of the air outlet 12, and a power cable 14 extended out of the peripheral wall 13.

The mounting frame 2 fits over the air outlet 12 of the fan 1, comprising a plurality of mounting devices, for example, mounting through holes 211 respectively disposed in the four corners thereof corresponding to the screw holes 121 of the fan 1 and respectively fastened to the screw holes 121 of the fan 1 with screws 3.

The mounting frame 2 further comprises a side plate 22 perpendicularly forwardly extended from one lateral side thereof. The side plate 22 has two through holes 221. After connection of the mounting frame 2 to the air outlet 12 of the fan 1, the side plate 22 is covered over the peripheral wall 13 of the fan 1 at one side, and the power cable 14 of the fan 1 is extended through one of the through holes 221 of the side plate 22 to the outside.

Referring to FIG. 4 and FIG. 2 and FIG. 3 again, the mounting frame 2 further comprises two sliding rails 23 symmetrically disposed at two opposite sides, and a top handle 222 upwardly extended from the side plate 22. After connection of the mounting frame 2 to the fan 1, the user can hold the top handle 222 with the hand to carry the assembly of the mounting frame 2 and the fan 1 to the job site and then to couple the sliding rails 23 to a fan bracket 4.

As indicated above, the mounting frame 2 is directly fastened to the border area of the air outlet 12 of the fan 1, and has only one side plate 22 extended from one lateral side for covering over one side of the peripheral wall 13 of the fan 1. Therefore, the mounting frame 2 fits any of a variety of fans that have different height. FIG. 4 shows a plurality of fans 1, 101, 102 having different height mounted with a respective mounting frame 2 in a fan bracket 4. The fans 1, 101, 102 have different shapes, for example, rectangular shape, circular shape, etc.

Although the present invention has been explained in relation to its preferred embodiment, it is to be understood that many other possible modifications and variations can be made without departing from the spirit and scope of the invention as hereinafter claimed.

1. A fan mounting structure comprising:
a fan, said fan comprising an air inlet, an air outlet opposite to said air inlet, a peripheral wall peripherally connected between said air inlet and said air outlet, and a plurality of mounting devices provided around one of said air inlet and said air outlet; and
a mounting frame adapted to secure one of said air inlet and said air outlet of said fan to a fan rack, said mounting frame comprising a plurality of mounting devices respectively fastened to the mounting devices of said fan, and a side plate perpendicularly extended from one lateral side thereof and covering over one lateral side of the peripheral wall of said fan.

2. The fan mounting structure as claimed in claim 1, wherein the side plate of said mounting frame further comprises at least one through hole; said fan further comprises a power cable extended through the at least one through hole of said side plate of said mounting frame to the outside.

3. The fan mounting structure as claimed in claim 1, wherein said mounting frame further comprises two sliding rails symmetrically disposed at two opposite lateral sides thereof for mounting.

4. The fan mounting structure as claimed in claim 1, wherein said mounting frame further comprises a handle upwardly extended from said side plate.

5. The fan mounting structure as claimed in claim 1, wherein the mounting devices of said fan are screw holes, and the mounting devices of said mounting frame are mounting through holes respectively fastened to the corresponding screw holes of said fan with respective screws.
